(19) United States
(12) Patent Application Publication
(10) Pub. No.: US 2024/0019646 A1
(43) Pub. Date: Jan. 18, 2024

(54) VERTICAL CAVITY SURFACE EMITTING LASER (VCSEL) INTEGRATION ON A PHOTONIC INTEGRATED CIRCUIT (PIC)

(71) Applicant: Meta Platforms Technologies, LLC, Menlo Park, CA (US)

(72) Inventor: Zhaoming ZHU, Redmond, WA (US)

(73) Assignee: Meta Platforms Technologies, LLC, Menlo Park, CA (US)

(21) Appl. No.: 18/077,523

(22) Filed: Dec. 8, 2022

Related U.S. Application Data
(60) Provisional application No. 63/388,567, filed on Jul. 12, 2022.

(51) Int. Cl. G02B 6/42; H01S 5/183

(52) U.S. Cl. CPC G02B 6/4215; H01S 5/18305; G02B 6/4239; G02B 6/4238

(57) ABSTRACT

An off-normal bottom-emitting vertical cavity surface emitting laser (VCSEL) is integrated with a photonic integrated circuit (PIC) for incident light from the VCSEL to efficiently couple to a waveguide via a grating coupler in the PIC. Diffraction of the light by the grating coupler is in a direction that is aligned with an input of the waveguide such that most or all of the light enters the waveguide. The off-normal VCSEL output is achieved by arranging an output facet at a bottom surface of the VCSEL with decentered micro-lenses, micro-prisms, gratings, diffractive optical elements, and/or metasurfaces. The diffractive optical elements or metasurfaces may also be used for beam divergence mitigation and/or polarization control.

### CROSS REFERENCE TO RELATED APPLICATIONS

This patent application claims the benefit of U.S. Provisional Patent Application Ser. No. 63/388,567 filed on Jul. 12, 2022. The disclosures of the above application are hereby incorporated by reference for all purposes.

### TECHNICAL FIELD

This patent application relates generally to vertical cavity surface emitting lasers (VCSELs), and specifically, to techniques for integrating a bottom-emitting vertical cavity surface emitting laser (VCSEL) for efficient coupling of light to a waveguide within a photonic integrated circuit (PIC) via a grating coupler.

### BACKGROUND

Photonic integrated circuits (PICs) or narrowly silicon photonics (SiPh) are finding applications in various new and emerging technology fields, such as communications, datacenters, computing, artificial intelligence, sensing, and augmented reality (AR)/virtual reality (VR) implementations. One challenge to photonic integrated circuit (PIC) or narrowly silicon photonics (SiPh) technologies is the integration of laser source. Heterogeneous integration of in-plane emitting (or edge emitting) lasers on photonic integrated circuits (PICs) for data communications is an exemplary implementation.

For some applications, such as short-distance transceivers, near-range 3D sensing (including eye-tracking on augmented reality (AR)/virtual reality (VR) implementations) and augmented reality (AR) display engine, a vertical cavity surface emitting laser (VCSEL) may be used as a laser source; however, techniques to integrate a vertical cavity surface emitting laser (VCSEL) with a photonic integrated circuit (PIC) may have low efficiency due to the 90-degree coupling of laser beam into a waveguide within the photonic integrated circuit (PIC).

### BRIEF DESCRIPTION OF DRAWINGS

Features of the present disclosure are illustrated by way of example and not limited in the following figures, in which like numerals indicate like elements. One skilled in the art will readily recognize from the following that alternative examples of the structures and methods illustrated in the figures can be employed without departing from the principles described herein.

FIG. 1A illustrates a perspective view of a near-eye display in form of a pair of augmented reality (AR) glasses, according to an example.

FIG. 1B illustrates a top view of a near-eye display in form of a pair of augmented reality (AR) glasses, according to an example.

FIG. 2A illustrates a side cross-sectional view of a vertical cavity surface emitting laser (VCSEL) integrated with a photonic integrated circuit (PIC) via solder bumps, according to an example.

FIG. 2B illustrates a side cross-sectional view of a vertical cavity surface emitting laser (VCSEL) integrated with a photonic integrated circuit (PIC) via adhesive attachment, according to an example.

FIGS. 3A and 3B illustrate side cross-sectional views of two vertical cavity surface emitting laser (VCSEL) output facet configurations, according to an example.

FIG. 4 illustrates a flowchart of a method for operating a vertical cavity surface emitting laser (VCSEL) integrated with a photonic integrated circuit (PIC), according to an example.

FIG. 5 illustrates a flowchart of a method for integrating a vertical cavity surface emitting laser (VCSEL) with a photonic integrated circuit (PIC), according to an example.

### DETAILED DESCRIPTION

For simplicity and illustrative purposes, the present application is described by referring mainly to examples thereof. In the following description, numerous specific details are set forth in order to provide a thorough understanding of the present application. It will be readily apparent, however, that the present application may be practiced without limitation to these specific details. In other instances, some methods and structures readily understood by one of ordinary skill in the art have not been described in detail so as not to unnecessarily obscure the present application. As used herein, the terms “a” and “an” are intended to denote at least one of a particular element, the term “includes” means includes but not limited to, the term “including” means including but not limited to, and the term “based on” means based at least in part on.

As used herein, a “near-eye display” may refer to any display device (e.g., an optical device) that may be in close proximity to a user's eye. As used herein, “artificial reality” may refer to aspects of, among other things, a “metaverse” or an environment of real and virtual elements and may include use of technologies associated with virtual reality (VR), augmented reality (AR), and/or mixed reality (MR). As used herein, a “user” may refer to a user or wearer of a “near-eye display.”

Some near-eye display devices may include displays, projectors, and/or eye-tracking sensors that use laser as light source, where light from the laser is coupled to a waveguide. For some applications such as short-distance transceivers, near-range 3D sensing (including eye-tracking on augmented reality (AR)/virtual reality (VR) implementations), and augmented reality (AR) display engine, vertical cavity surface emitting laser (VCSEL) may be the preferred laser source. However, a vertical cavity surface emitting laser (VCSEL) integration with a photonic integrated circuit (PIC) may have low efficiency and higher power consumption (for high brightness applications) due to the 90-degree coupling of laser beam into a waveguide within the photonic integrated circuit (PIC).

In some examples of the present disclosure, an off-normal bottom-emitting vertical cavity surface emitting laser (VCSEL) may be integrated with a photonic integrated circuit (PIC) such that the off-normal incident light from the vertical cavity surface emitting laser (VCSEL) can be efficiently coupled to a waveguide via a grating coupler in the photonic integrated circuit (PIC). “Coupling” of the light into the waveguide by the grating coupler, as used herein, refers to diffraction of the light by the grating coupler in a direction that is aligned with an input of the waveguide such that the most or all of the light enters the waveguide. The off-normal vertical cavity surface emitting laser (VCSEL) output may be achieved by processing an output facet at a bottom surface of the vertical cavity surface emitting laser (VCSEL) (e.g., an angled facet, a decentered micro-lens, micro-prisms, gratings, diffractive optical elements, and/or metasurfaces). The use of diffractive optical elements or metasurfaces may enable additional functions such as beam divergence mitigation and polarization control. The off-normal incident light may be coupled to a waveguide in the photonic integrated circuit (PIC) through a grating coupler, which may also increase an efficiency of coupling for the photonic integrated circuit (PIC). An example range for incidence angle may be between about 5 degrees and about 15 degrees. Other incidence angles may also be used.

While some advantages and benefits of the present disclosure are apparent, other advantages and benefits may include ease of fabrication by integrating the vertical cavity surface emitting laser (VCSEL) with the photonic integrated circuit (PIC) through flip-chip bonding without tilting the vertical cavity surface emitting laser (VCSEL) chip or the photonic integrated circuit (PIC) wafer, or chip/wafer to wafer adhesive bonding. Optimized grating coupler designs may be used for off-normal light coupling to waveguides in the photonic integrated circuit (PIC) instead of specialized and complex designs for 90-degree coupling. A disturbance to the laser due to reflected light back into the laser cavity may be reduced or eliminated providing enhanced laser stability without extended laser cavity complication. Furthermore, additional optical processing may be performed by the output facet of the vertical cavity surface emitting laser (VCSEL) such as anti-reflection coatings for improved transmission, beam collimation, spatial and/or spectral filtering, and/or polarization control.

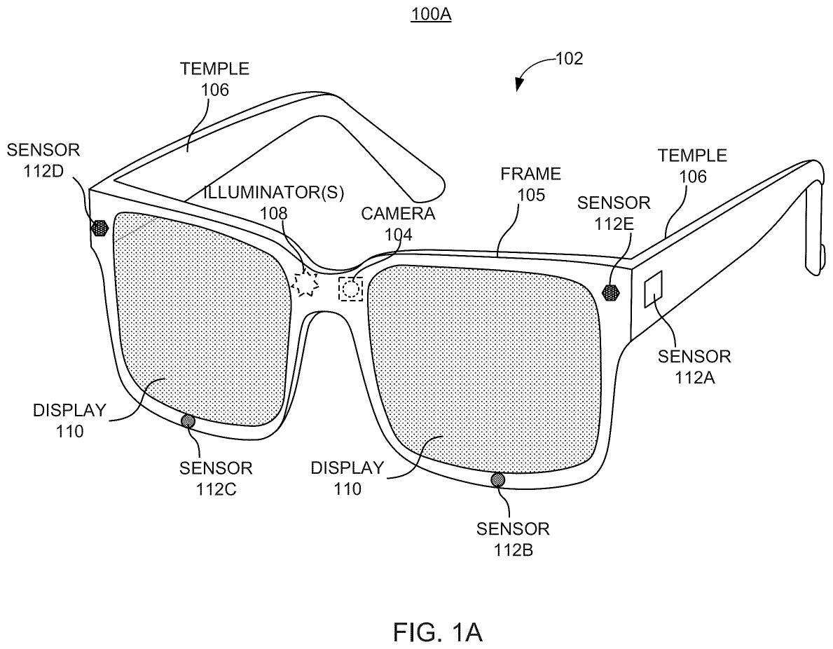

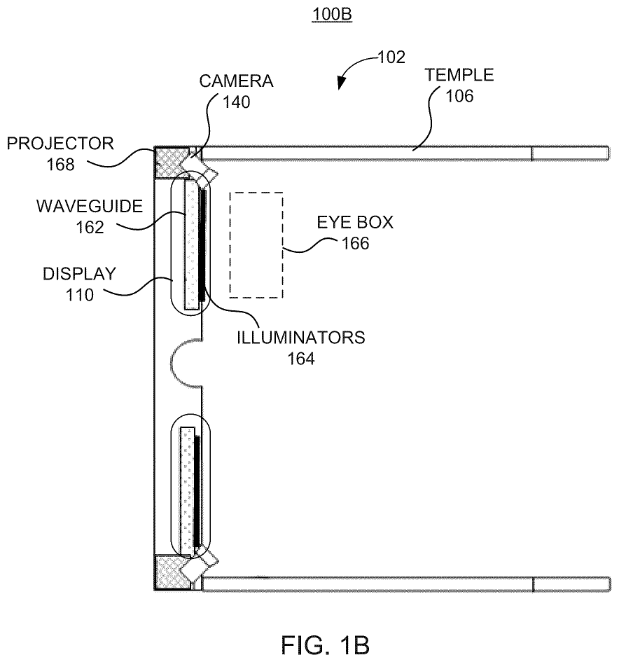

FIG. 1A is a perspective view of a near-eye display 102 in the form of a pair of glasses (or other similar eyewear), according to an example. In some examples, the near-eye display 102 may be configured to operate as a virtual reality display, an augmented reality (AR) display, and/or a mixed reality (MR) display.

As shown in diagram 100A, the near-eye display 102 may include a frame 105 and a display 110. In some examples, the display 110 may be configured to present media or other content to a user. In some examples, the display 110 may include display electronics and/or display optics. For example, the display 110 may include a liquid crystal display (LCD) display panel, a light-emitting diode (LED) display panel, or an optical display panel (e.g., a waveguide display assembly). In some examples, the display 110 may also include any number of optical components, such as waveguides, gratings, lenses, mirrors, etc. In other examples, the display 110 may include a projector, or in place of the display 110 the near-eye display 102 may include a projector. The projector may use laser light to form an image in angular domain on an eye box for direct observation by a viewer's eye and may include a vertical cavity surface emitting laser (VCSEL) emitting light at an off-normal angle integrated with a photonic integrated circuit (PIC) for high efficiency and reduced power consumption.

In some examples, the near-eye display 102 may further include various sensors 112A, 112B, 112C, 112D, and 112E on or within a frame 105. In some examples, the various sensors 112A-112E may include any number of depth sensors, motion sensors, position sensors, inertial sensors, and/or ambient light sensors, as shown. In some examples, the various sensors 112A-112E may include any number of image sensors configured to generate image data representing different fields of views in one or more different directions. In some examples, the various sensors 112A-112E may be used as input devices to control or influence the displayed content of the near-eye display, and/or to provide an interactive virtual reality (VR), augmented reality (AR), and/or mixed reality (MR) experience to a user of the near-eye display 102. In some examples, the various sensors 112A-112E may also be used for stereoscopic imaging or other similar application.

In some examples, the near-eye display 102 may further include one or more illuminators 108 to project light into a physical environment. The projected light may be associated with different frequency bands (e.g., visible light, infra-red light, ultra-violet light, etc.), and may serve various purposes. In some examples, the one or more illuminator(s) 108 may be used as locators.

In some examples, the near-eye display 102 may also include a camera 104 or other image capture unit. The camera 104, for instance, may capture images of the physical environment in the field of view. In some instances, the captured images may be processed, for example, by a virtual reality engine to add virtual objects to the captured images or modify physical objects in the captured images, and the processed images may be displayed to the user by the display 110 for augmented reality (AR) and/or mixed reality (MR) applications.

FIG. 1B is a top view of a near-eye display 102 in the form of a pair of glasses (or other similar eyewear), according to an example. As shown in diagram 100B, the near-eye display 102 may include a frame 105 having a form factor of a pair of eyeglasses. The frame 105 supports, for each eye: a scanning projector 168 such as any scanning projector variant considered herein, a pupil-replicating waveguide 162 optically coupled to the projector 168, an eye-tracking camera 140, and a plurality of illuminators 164. The illuminators 164 may be supported by the pupil-replicating waveguide 162 for illuminating an eye box 166. The projector 168 may provide a fan of light beams carrying an image in angular domain to be projected into a user's eye. The projector 168 may include a vertical cavity surface emitting laser (VCSEL) emitting light at an off-normal angle integrated with a photonic integrated circuit (PIC) for high efficiency and reduced power consumption.

In some examples, multi-emitter laser sources may be used in the projector 168. Each emitter of the multi-emitter laser chip may be configured to emit image light at an emission wavelength of a same color channel. The emission wavelengths of different emitters of the same multi-emitter laser chip may occupy a spectral band having the spectral width of the laser source. The projector 168 may include, for example, two or more multi-emitter laser chips emitting light at wavelengths of a same color channel or different color channels. For augmented reality (AR) applications, the pupil-replicating waveguide 162 may be transparent or translucent to enable the user to view the outside world together with the images projected into each eye and superimposed with the outside world view. The images projected into each eye may include objects disposed with a simulated parallax, so as to appear immersed into the real-world view.

The eye-tracking camera 140 may be used to determine position and/or orientation of both eyes of the user. Once the position and orientation of the user's eyes are known, a gaze convergence distance and direction may be determined. The imagery displayed by the projector 168 may be adjusted dynamically to account for the user's gaze, for a better fidelity of immersion of the user into the displayed augmented reality scenery, and/or to provide specific functions of interaction with the augmented reality. In operation, the illuminators 164 may illuminate the eyes at the corresponding eye boxes 166, to enable the eye-tracking cameras to obtain the images of the eyes, as well as to provide reference reflections. The reflections (also referred to as “glints”) may function as reference points in the captured eye image, facilitating the eye gazing direction determination by determining position of the eye pupil images relative to the glints. To avoid distracting the user with illuminating light, the latter may be made invisible to the user. For example, infrared light may be used to illuminate the eye boxes 166.

In some examples, the image processing and eye position/orientation determination functions may be performed by a central controller, not shown, of the near-eye display 102. The central controller may also provide control signals to the projectors 168 to generate the images to be displayed to the user, depending on the determined eye positions, eye orientations, gaze directions, eyes vergence, etc.

Functions described herein may be distributed among components of the near-eye display 102 in a different manner than is described here. Furthermore, a near-eye display as discussed herein may be implemented with additional or fewer components than shown in FIGS. 1A and 1B. While the near-eye display 102 is shown and described in form of glasses, a vertical cavity surface emitting laser (VCSEL) integrated with a photonic integrated circuit (PIC) may be implemented in other forms of near-eye displays such as goggles or headsets, as well as in non-wearable display systems.

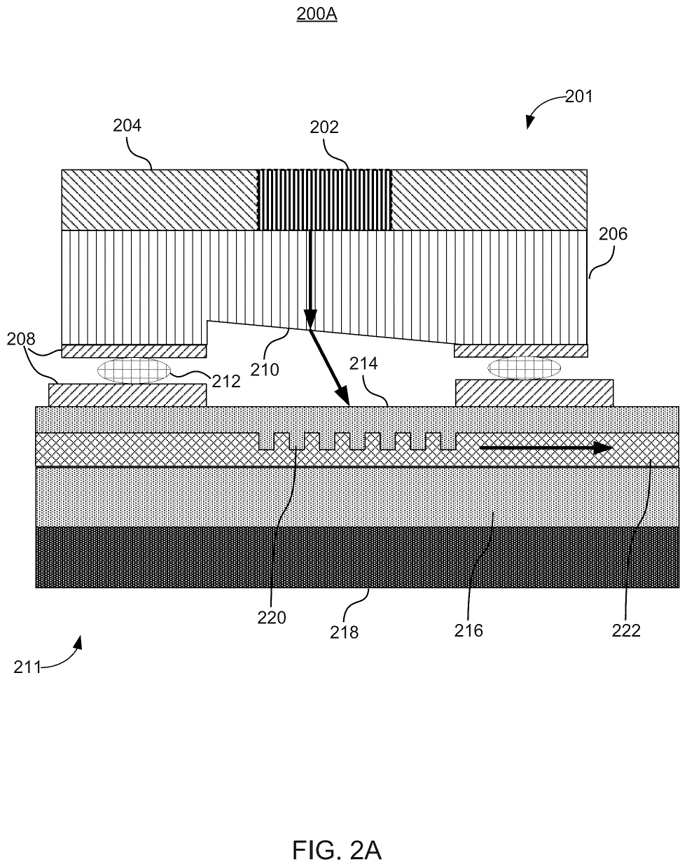

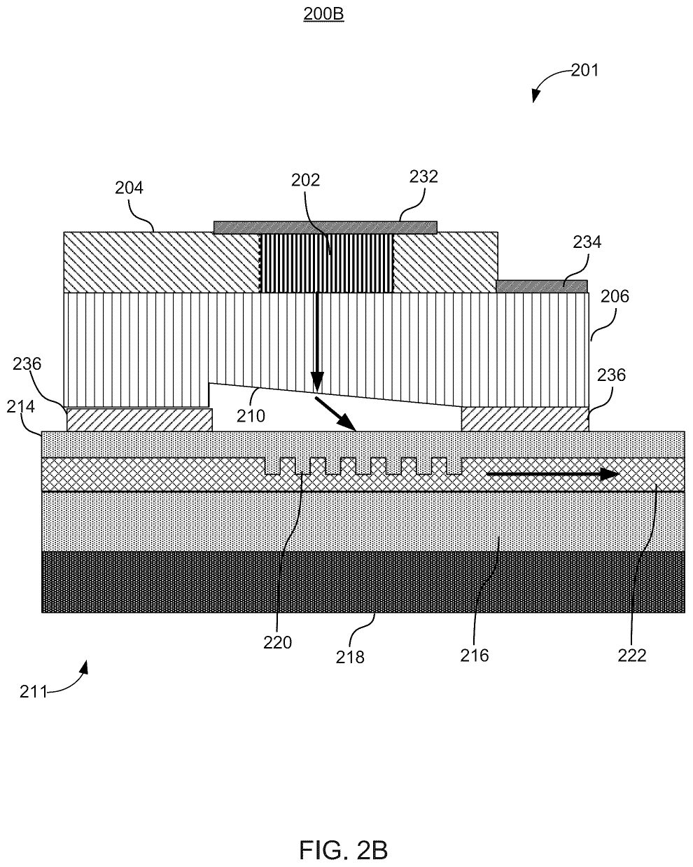

FIG. 2A illustrates a side cross-sectional view of a vertical cavity surface emitting laser (VCSEL) integrated with a photonic integrated circuit (PIC) via solder bumps, according to an example. Diagram 200A shows a vertical cavity surface emitting laser (VCSEL) 201 with a vertical cavity surface emitting laser (VCSEL) cavity 202 (also referred to as quantum well region sandwiched by top and bottom Bragg mirrors), a Bragg mirror region 204 surrounding the quantum well, and a substrate 206. The vertical cavity surface emitting laser (VCSEL) 201 is a bottom-emitting laser, and an output facet 210 at the bottom of the laser may be formed at an angle (e.g., through etching) such that emitted light leaves the output facet 210 at an angle off the normal.

Diagram 200A also shows a photonic integrated circuit (PIC) 211 with a first layer 214, a second layer 222, a third layer 216, and a wafer 218. The first layer 214 and the third layer 216 may be formed with silicon dioxide (SiO2), and the wafer 218 may be formed with silicon. The second layer 222 may be formed with silicon (Si) or silicon nitrogen (SiN) and include a grating coupler 220, which may diffract (and direct) incident light to a waveguide within the second layer 222 (not shown). Thus, the incident light arriving at an off-normal angle may be diffracted to an angle parallel to the plane of the second layer 222 by the grating coupler 220.

In an example implementation, the vertical cavity surface emitting laser (VCSEL) 201 may be fabricated with a top p+ GaAs layer followed by 30 layers of alternating p-AlGaAs and GaAs forming the upper Bragg reflector and 17.5 layers of alternating n-AlAs and GaAs forming the lower Bragg reflector over an n-GaAs substrate. The quantum well may be formed between the upper and lower Bragg reflectors with an oxide layer (current confinement layer) between the upper Bragg reflector and the quantum well. The quantum well may include three InGaAs quantum well layers separated by GaAs quarter wave (QVV) barriers sandwiched between two AlGaAs confinement layers.

In some examples, the vertical cavity surface emitting laser (VCSEL) and the photonic integrated circuit (PIC) may be integrated through solder connection (solder bumps 212) between bond pads 208 at a bottom surface of the vertical cavity surface emitting laser (VCSEL) and a top surface of the first layer 214 of the photonic integrated circuit (PIC). This is also referred to as flip-chip bonding, where the vertical cavity surface emitting laser (VCSEL) chip is flipped and solder-bonded with a corresponding photonic integrated circuit (PIC) on a wafer during fabrication. The bond pads may be used as p- and n-contacts. The output facet 210 may be “aligned” with the grating coupler 220 such that most or all of the light emitted by the vertical cavity surface emitting laser (VCSEL) is captured by the grating coupler 220 to avoid any coupling losses between the vertical cavity surface emitting laser (VCSEL) and the photonic integrated circuit (PIC).

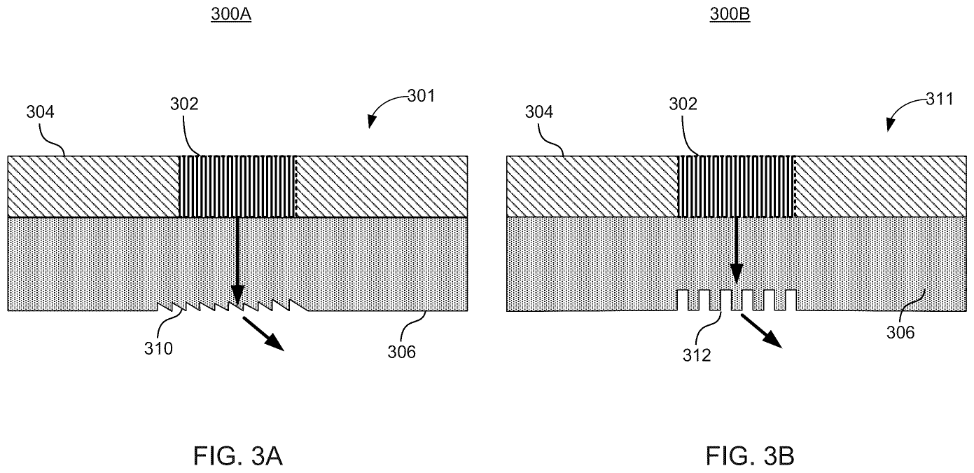

In some examples, the angled output facet 210 is one example of achieving off-normal exit angle for the light beam generated by the vertical cavity surface emitting laser (VCSEL). Other light-bending structures such as diffractive optical structures, decentered micro-lenses, gratings, metasurfaces, etc. may also be used, as discussed below in conjunction with FIGS. 3A and 3B. By bending the exiting light off the normal, a back-reflection from the photonic integrated circuit (PIC) into the vertical cavity surface emitting laser (VCSEL) cavity may be reduced or eliminated, which may provide increased laser stability and allow higher power output (without a need for protective measures for the cavity). Also, it may be used to have anti-reflection coatings to increase light transmission while reducing light back reflection at the output facet. Furthermore, the grating coupler 220 in a vertical light-coupling configuration may have to be specially designed to provide 90-degree diffraction for coupling into the waveguide. With the incident light at an off-normal angle (non-90-degree), the grating coupler 220 may also be designed with increased simplicity while enhancing coupling efficiency for the photonic integrated circuit (PIC).

In some examples, vertical cavity surface emitting laser (VCSEL) output facet size may depend on the vertical cavity design (oxide aperture size, beam divergence) and substrate thickness (may be 100 μm or less). A single-mode, bottom-emitting vertical cavity surface emitting laser (VCSEL) output facet diameter may, in some examples, range from about 10 μm to a few tens of micrometers.

In some examples, the vertical cavity surface emitting laser (VCSEL) may have characteristics such as single polarization and/or low divergence to achieve high coupling efficiency into the photonic integrated circuit (PIC) via optimized grating couplers. Such characteristics may be achieved through laser cavity design. Additionally or alternatively, the various structures (used in place of or in addition to the angled surface) for the output facet 210 may also be used to control various characteristics of the emitted light. For example, the emitted light may be focused, filtered, polarized, or comparably processed. In some examples, an output facet angle may be selected to be Brewster angle to achieve highly polarized output to improve coupling efficiency. Brewster angle (also referred to as the polarization angle) is an angle of incidence at which light with a particular polarization is transmitted through a transparent dielectric surface with no reflection. When unpolarized light is incident at this angle, the light that is reflected from the surface may therefore be perfectly polarized.

In some examples, an array vertical cavity surface emitting lasers (VCSELs) may be integrated with a photonic integrated circuit (PIC), where each vertical cavity surface emitting laser (VCSEL) has its corresponding grating coupler and waveguide. The light in these waveguides may be separately processed by components in the photonic integrated circuit (PIC) to achieve massive parallel processing capability or may be combined by a multi-to-one (N×1) coupler to combine the lights together to achieve higher power.

FIG. 2B illustrates a side cross-sectional view of a vertical cavity surface emitting laser (VCSEL) integrated with a photonic integrated circuit (PIC) via adhesive bonding, according to an example. Diagram 200B shows a vertical cavity surface emitting laser (VCSEL) 201 with a vertical cavity surface emitting laser (VCSEL) cavity 202 (also referred to as quantum well), a Bragg mirror region 204 surrounding the quantum well, and a substrate 206. The vertical cavity surface emitting laser (VCSEL) 201 is a bottom-emitting laser, and an output facet 210 at the bottom of the laser may be formed at an angle (e.g., through etching) such that emitted light leaves the output facet 210 at an angle off the normal.

Diagram 200B also shows a photonic integrated circuit (PIC) 211 with a first layer 214, a second layer 222, a third layer 216, and a substrate 218. The first layer 214 and the third layer 216 may be formed with silicon dioxide (SiO2), and the substrate 218 may be formed with silicon. The second layer 222 may be formed with silicon (Si) or silicon nitrogen (SiN) and include a grating coupler 220, which may diffract (and direct) incident light to a waveguide within the second layer 222 (not shown). Thus, the incident light arriving at an off-normal angle may be diffracted to an angle parallel to the plane of the second layer 222 by the grating coupler 220. The vertical cavity surface emitting laser (VCSEL) 201 and the photonic integrated circuit (PIC) 211 may be integrated through adhesive bonding 236 at a bottom surface of the vertical cavity surface emitting laser (VCSEL) and a top surface of the first layer 214 of the photonic integrated circuit (PIC). In case of adhesive bonding 236, the p-contact 232 and the n-contact 234 may be formed on a top surface of the vertical cavity surface emitting laser (VCSEL) 201.

In some examples, the vertical cavity surface emitting laser (VCSEL) 201 may be a single wavelength laser or a multi-wavelength laser. The vertical cavity surface emitting laser (VCSEL) 201 may also provide light in visible light spectrum, near-infrared (NIR) spectrum, or infrared (IR) spectrum. The vertical cavity surface emitting laser (VCSEL), photonic integrated circuit (PIC) combination may be used as a photonic integrated circuit (PIC) structured light (e.g., interferometric fringe) projector for near-range 3D sensing (e.g., eye tracking, hand tracking, body tracking, etc.) in augmented reality (AR)/virtual reality (VR) devices.

While example materials (e.g., silicon “Si”, silicon oxide “SiO2”, silicon nitride “SiN”, gallium arsenide “GaAs”) are provided as illustrative examples herein, implementations are not limited to these materials. Other materials such as indium phosphide, aluminum gallium arsenide, and similar ones may also be used for various layers of the photonic integrated circuit (PIC) and the vertical cavity surface emitting laser (VCSEL).

FIGS. 3A and 3B illustrate side cross-sectional views of two vertical cavity surface emitting laser (VCSEL) output facet configurations, according to an example. Diagram 300A in FIG. 3A shows a vertical cavity surface emitting laser (VCSEL) 301 with a vertical cavity surface emitting laser (VCSEL) cavity 302, a Bragg mirror region 304 surrounding the cavity, and a substrate 306. The vertical cavity surface emitting laser (VCSEL) 301 is a bottom-emitting laser, and an output facet 310 at the bottom of the laser may be formed with diffractive optical elements such as micro-prisms, grating, or comparable elements. The diffractive output facet 310 may provide exiting light at an angle that is off the normal (non-90 degree to a receiving surface of a photonic integrated circuit “PIC”) allowing higher efficiency coupling and more power for the integrated device.

Diagram 300B in FIG. 3B shows a vertical cavity surface emitting laser (VCSEL) 311 with a vertical cavity surface emitting laser (VCSEL) cavity 302 (also referred to as quantum well), a Bragg mirror region 304 surrounding the quantum well, and a substrate 306. The vertical cavity surface emitting laser (VCSEL) 301 is a bottom-emitting laser, and an output facet 312 at the bottom of the laser may be formed with diffractive metasurfaces. The output facet 312 with the metasurfaces may provide exiting light at an angle that is off the normal (non-degree to a receiving surface of a photonic integrated circuit “PIC”) allowing higher efficiency coupling and more power for the integrated device. The metasurfaces may include a square post, a rectangular post, a cylinder, an irregular post, or comparable shapes.

Additionally, the diffractive optical elements (specifically, the metasurfaces) may be configured to provide additional functionality such as focusing, filtering, polarization, etc. The output facet 312 may also be appropriately coated with antireflective coating to improve light transmission. In further examples, the output facet 310 or 312 may also be formed as a curved refractive surface using free-form elements (e.g., a simple refractive element is a positive micro-lens which is decentered from incident VCSEL beam, leading to off-normal output beam which is also less divergent due to the collimation by the micro-lens).

In some implementations, the laser resonator may include two distributed Bragg reflector (DBR) mirrors parallel to the wafer surface with an active region consisting of one or more quantum wells for the laser light generation in between. The planar DBR-mirrors may include layers with alternating high and low refractive indices. Each layer may have a thickness of a quarter of the laser wavelength in the material, yielding intensity reflectivity above 99%. High reflectivity mirrors may balance the short axial length of the gain region of the vertical cavity surface emitting laser (VCSEL). In some implementations, the active regions may comprise several multiple quantum wells (MQW) separated by tunnel junctions to boost laser output power and efficiency (the so-called multi-junction VCSEL).

In vertical cavity surface emitting lasers (VCSELs), the upper and lower mirrors may be doped as p-type and n-type materials, forming a diode junction. In more complex structures, the p-type and n-type regions may be embedded between the mirrors, requiring a more complex semiconductor process to make electrical contact to the active region, but eliminating electrical power loss in the distributed Bragg reflector (DBR) structure.

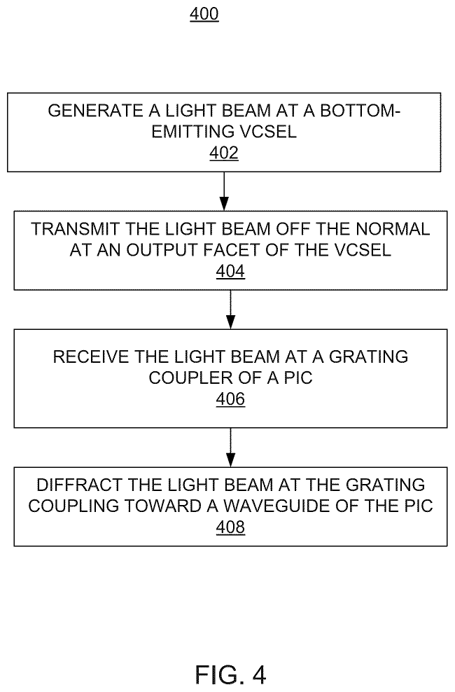

FIG. 4 illustrates a flowchart of a method for operating a vertical cavity surface emitting laser (VCSEL) integrated with a photonic integrated circuit (PIC), according to an example. The method 400 is provided by way of example, as there may be a variety of ways to carry out the method described herein. Although the method 400 is primarily described as being performed by the models of FIGS. 2A and 2B, the method 400 may be executed or otherwise performed by one or more processing components of another system or a combination of systems to implement other models. Each block shown in FIG. 4 may further represent one or more processes, methods, or subroutines, and one or more of the blocks may include machine readable instructions stored on a non-transitory computer readable medium and executed by a processor or other type of processing circuit to perform one or more operations described herein.

At block 402, a laser light beam may be generated in a quantum well of a vertical cavity surface emitting laser (VCSEL) 201 directed to the output facet 210 of the vertical cavity surface emitting laser (VCSEL) 201, which may be a bottom-emitting laser.

At block 404, the light beam may be diffracted (or refracted) by the output facet 210 off normal. The output facet 210 may be an angled surface and/or include diffractive elements such as micro-prisms, a grating, metasurfaces, free-form elements, and the like.

At block 406, the off-normal, angled light beam may be received (through a top surface) at a grating coupler 220 of a photonic integrated circuit (PIC) 211. Because the incident light is angled as opposed to in normal direction, the grating coupler 220 may not need to be highly complex designs for 90-degree diffraction and allow for higher coupling efficiency.

At block 408, the grating coupler 220 of the photonic integrated circuit (PIC) 211 may diffract the incident light beam and couple to a waveguide of the photonic integrated circuit (PIC) 211, which may provide the light to other optical elements of a near-eye display device, for example.

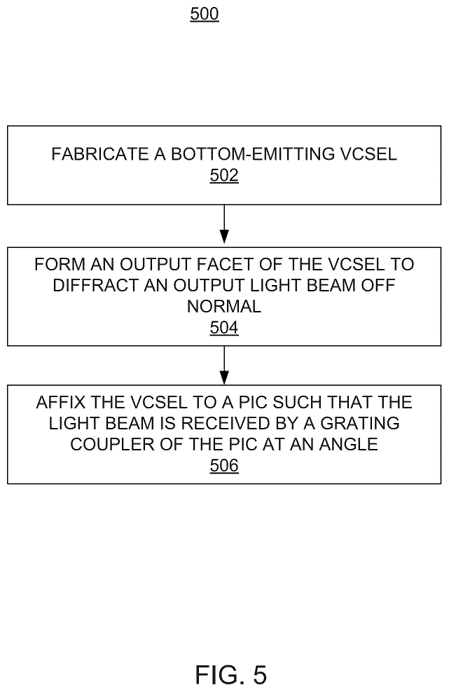

FIG. 5 illustrates a flowchart of a method for integrating a vertical cavity surface emitting laser (VCSEL) with a photonic integrated circuit (PIC), according to an example. The method 500 is provided by way of example, as there may be a variety of ways to carry out the method described herein. Although the method 500 is primarily described as being performed to implement the models of FIGS. 2A and 2B, the method 500 may be executed or otherwise performed by one or more processing components of another system or a combination of systems to implement other models. Each block shown in Figure may further represent one or more processes, methods, or subroutines, and one or more of the blocks may include machine readable instructions stored on a non-transitory computer readable medium and executed by a processor or other type of processing circuit to perform one or more operations described herein.

At block 502, a bottom-emitting a vertical cavity surface emitting laser (VCSEL) 201 may be fabricated with its a vertical cavity surface emitting laser (VCSEL) cavity 202, Bragg region 204, and substrate 206.

At block 504, an output facet 210 may be formed at a bottom surface of the substrate 206. The output facet 210 may be formed as an angled surface and/or include diffractive elements such as micro-prisms, a grating, metasurfaces, free-form elements, and the like, to diffract or refract the exiting light beam off the normal.

At block 506, the vertical cavity surface emitting laser (VCSEL) 201 may be integrated with the photonic integrated circuit (PIC) 211 through flip-chip solder bonding or adhesive bonding such that the light beam is received by a grating coupler of the photonic integrated circuit (PIC) 211 at an off-normal (non-angle by design.

According to examples, a method of integrating a vertical cavity surface emitting laser (VCSEL) with a photonic integrated circuit (PIC) is described herein. A system of making the vertical cavity surface emitting laser (VCSEL) with a photonic integrated circuit (PIC) is also described herein. A non-transitory computer-readable storage medium may have an executable stored thereon, which when executed instructs a processor to perform the methods described herein.

In the foregoing description, various inventive examples are described, including devices, systems, methods, and the like. For the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples.

The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example’ is not necessarily to be construed as preferred or advantageous over other embodiments or designs.

Although the methods and systems as described herein may be directed mainly to digital content, such as videos or interactive media, it should be appreciated that the methods and systems as described herein may be used for other types of content or scenarios as well. Other applications or uses of the methods and systems as described herein may also include social networking, marketing, content-based recommendation engines, and/or other types of knowledge or data-driven systems.

1. An apparatus, comprising:
a vertical cavity surface emitting laser (VCSEL) to generate a laser beam, wherein an output facet at a bottom surface of the vertical cavity surface emitting laser (VCSEL) is arranged to transmit the laser beam at an off-normal angle; and
a photonic integrated circuit (PIC) comprising a grating coupler and a waveguide, wherein:
the grating coupler is to receive the laser beam from the vertical cavity surface emitting laser (VCSEL) at the off-normal angle and to diffract the to laser beam to couple to the waveguide, and
the vertical cavity surface emitting laser (VCSEL) is coupled to the photonic integrated circuit (PIC) such that the output facet is aligned with the grating coupler.

2. The apparatus of claim 1, wherein the vertical cavity surface emitting laser (VCSEL) and the photonic integrated circuit (PIC) are coupled through a flip-chip solder bonding technique or an adhesive bonding technique.

3. The apparatus of claim 1, wherein the output facet comprises an angled flat surface.

4. The apparatus of claim 3, wherein the angled flat surface is formed by etching.

5. The apparatus of claim 1, wherein the output facet comprises a plurality of micro-prisms, a grating, a metasurface, or a curved surface comprising free-form elements.

6. The apparatus of claim 5, wherein a shape of the metasurface comprises a square post, a rectangular post, a cylinder, or an irregular post.

7. The apparatus of claim 1, further comprising:
one or more optical elements on a bottom surface of the output facet to filter, focus, or polarize the laser beam.

8. The apparatus of claim 1, wherein the laser beam is in one of a visible light spectrum, a near-infrared (NIR) spectrum, or an infrared (IR) spectrum.

9. The apparatus of claim 1, wherein the grating coupler is to diffract the laser beam from vertical cavity surface emitting laser (VCSEL) in a direction aligned with an input of the waveguide.

10. An apparatus, comprising:
a plurality of vertical cavity surface emitting lasers (VCSELs) to generate a laser beam, wherein an output facet at a bottom surface of each vertical cavity surface emitting laser (VCSEL) is arranged to transmit the laser beam at an off-normal angle; and
a photonic integrated circuit (PIC) comprising a plurality of grating couplers and a waveguide, wherein
each grating coupler is to receive the laser beam at the off-normal angle from a vertical cavity surface emitting laser (VCSEL) and to diffract the laser beam to couple to the waveguide, and
the plurality of vertical cavity surface emitting lasers (VCSELs) are coupled to the photonic integrated circuit (PIC) such that each output facet is aligned with a corresponding grating coupler.

11. The apparatus of claim 10, wherein
the photonic integrated circuit (PIC) further comprises a multiple-to-one coupler between the plurality of grating couplers and the waveguide, and
the multiple-to-one coupler is to combine diffracted laser beams from the plurality of grating couplers and couple to the waveguide.

12. The apparatus of claim 10, wherein the output facet comprises an angled flat surface.

13. The apparatus of claim 10, wherein the output facet comprises a plurality of micro-prisms, a grating, a metasurface, or a curved surface comprising free-form elements.

14. The apparatus of claim 13, wherein a shape of the metasurface comprises a square post, a rectangular post, a cylinder, or an irregular post.

15. The apparatus of claim 10, further comprising:
one or more optical elements on a bottom surface of the output facet to filter, focus, or polarize the laser beam.

16. A method comprising:
generating a laser beam at a bottom-emitting vertical cavity surface emitting laser (VCSEL);
transmitting the laser beam off a normal at an output facet of the vertical cavity surface emitting laser (VCSEL);
receiving the laser beam from the vertical cavity surface emitting laser (VCSEL) at a grating coupler of a photonic integrated circuit (PIC), wherein the vertical cavity surface emitting laser (VCSEL) is coupled to the photonic integrated circuit (PIC) such that the output facet is aligned with the grating coupler; and
diffracting the laser beam at the grating coupler to a waveguide of the photonic integrated circuit (PIC).

17. The method of claim 16, wherein the vertical cavity surface emitting laser (VCSEL) and the photonic integrated circuit (PIC) are coupled through a flip-chip solder bonding technique or an adhesive bonding technique.

18. The method of claim 16, wherein transmitting the laser beam off the normal at the output facet comprises refracting the laser beam at an angled flat surface formed by etching.

19. The method of claim 16, wherein transmitting the laser beam off the normal at the output facet comprises refracting and/or diffracting the laser beam at one of a plurality of micro-prisms, a grating, a metasurface, or a curved surface comprising free-form elements.

20. The method of claim 16, further comprising:
one or more of filtering, focusing, or polarizing the laser beam through one or more optical elements on a bottom surface of the output facet.
